(19) United States
(12) Patent Application Publication
(10) Pub. No.: US 2025/0142966 A1
(43) Pub. Date: May 1, 2025

(54) ELECTRONIC DEVICE

(71) Applicant: AUO Corporation, Hsinchu City (TW)

(72) Inventors: Wei Ting Liu, Hsinchu City (TW); Chih-Tsung Lee, Hsinchu City (TW); Shang-Ren Lin, Hsinchu City (TW); Yu-Chin Wu, Hsinchu City (TW)

(73) Assignee: AUO Corporation, Hsinchu City (TW)

(21) Appl. No.: 18/902,958

(22) Filed: Oct. 1, 2024

(30) Foreign Application Priority Data
Oct. 30, 2023 (TW) 112141539

(51) Int. Cl. H01L 27/12; B81B 3/00; H01L 25/16

(52) U.S. Cl. CPC H10D 86/60; B81B 3/0021; H01L 25/167; H10D 86/451; H10D 86/481; B81B 2203/0127

(57) ABSTRACT

An electronic device includes an element layer and transducing structures. The element layer includes island portions, bridge portions and openings. The island portions have pixel structures. Each of the pixel structures includes a thin film transistor and at least one light-emitting element electrically connected to the thin film transistor. The bridge portions connect the island portions. The island portions and the bridge portions define the openings. Each of the openings has a top side and a bottom side opposite to each other. The at least one light emitting element is located on the top side. Each of the transducing structures overlaps a corresponding opening. Each of the transducing structures includes a first electrode disposed on the bottom side of the opening 10 and a second electrode disposed on the top side of the opening, wherein a portion of the opening is a cavity of the transducing structure.

### CROSS-REFERENCE TO RELATED APPLICATION

This application claims the priority benefit of Taiwan application serial no. 112141539, filed on Oct. 30, 2023. The entirety of the above-mentioned patent application is hereby incorporated by reference herein and made a part of this specification.

### BACKGROUND

### Technical Field

The disclosure relates to an electronic device.

### Description of Related Art

Ultrasonic transducers include a bulk piezoelectric ceramic transducer, a capacitive micro machined ultrasonic transducer and a piezoelectric micro machined ultrasonic transducer. In recent years, many manufacturers and research units have invested in the development of capacitive micro machined ultrasonic transducers. This technology uses semiconductor manufacturing processes to miniaturize the ultrasonic transducer. Compared with traditional bulk piezoelectric materials, it is easier to integrate into various products.

The capacitive micro machined ultrasonic transducer includes a first electrode, an oscillating membrane located above the first electrode, and a second electrode located on the oscillating membrane, wherein there is a cavity between the first electrode and the oscillating membrane. An electric field between the first electrode and the second electrode can cause the oscillating membrane to swing in the cavity, thereby emitting ultrasonic waves. However, the thickness of traditional micro machined ultrasonic transducers is relatively thick. When the micro machined ultrasonic transducer is assembled on an electronic device, it will make it difficult for the electronic device to be thinned.

### SUMMARY

This disclosure provides an electronic device that integrates display and energy conversion functions and has the advantage of being thin.

An electronic device of this disclosure includes an element layer and transducing structures. The element layer includes island portions, bridge portions and openings. The island portions have pixel structures. Each of the pixel structure includes a thin film transistor and at least one light emitting element electrically connected to the thin film transistor. The bridge portions connect island portions. Each of the bridge portions has at least one wire. Wires of the bridge portions are electrically connected to the pixel structures. The island portions and the bridge portions define the openings. Each of the opening has a top side and a bottom side opposite to each other, and the at least one light emitting element is located on the top side. Each of the transducing structures overlaps an opening of the openings. Each of the transducing structures includes a first electrode disposed on the bottom side of the opening and a second electrode disposed on the top side of the opening, wherein a portion of the opening is the cavity of the each of the transducing structures.

### BRIEF DESCRIPTION OF THE DRAWINGS

FIGS. 1A to 1I are schematic cross-sectional views of the manufacturing process of an electronic device according to one embodiment of this disclosure.

FIG. 2 is a schematic top view of an electronic device according to an embodiment of the present disclosure.

FIG. 3 is a partially enlarged schematic diagram of an electronic device according to an embodiment of this disclosure.

FIG. 4 is a schematic cross-sectional view of an electronic device according to another embodiment of the present disclosure.

FIG. 5 is a schematic top view of the insulation layer, the intermediate dielectric layer and the deformation suppression structure of the electronic device according to another embodiment of the present disclosure.

FIG. 6 is a schematic bottom view of the base, buffer layer and the deformation suppression structure of the electronic device of another embodiment of the disclosure.

FIG. 7 is a top view and enlarged schematic diagram of an electronic device according to another embodiment of the disclosure.

FIG. 8 is a schematic cross-sectional view of an electronic device according to another embodiment of the present disclosure.

FIG. 9 is a schematic three-dimensional view of the first electrode and the second electrode of the transducing structure of the electronic device according to another embodiment of the present disclosure.

FIGS. 10A to 10L are schematic cross-sectional views of the manufacturing process of an electronic device according to yet another embodiment of the present disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the invention and will not be interpreted in an idealized or overly formal sense unless expressly so defined herein.

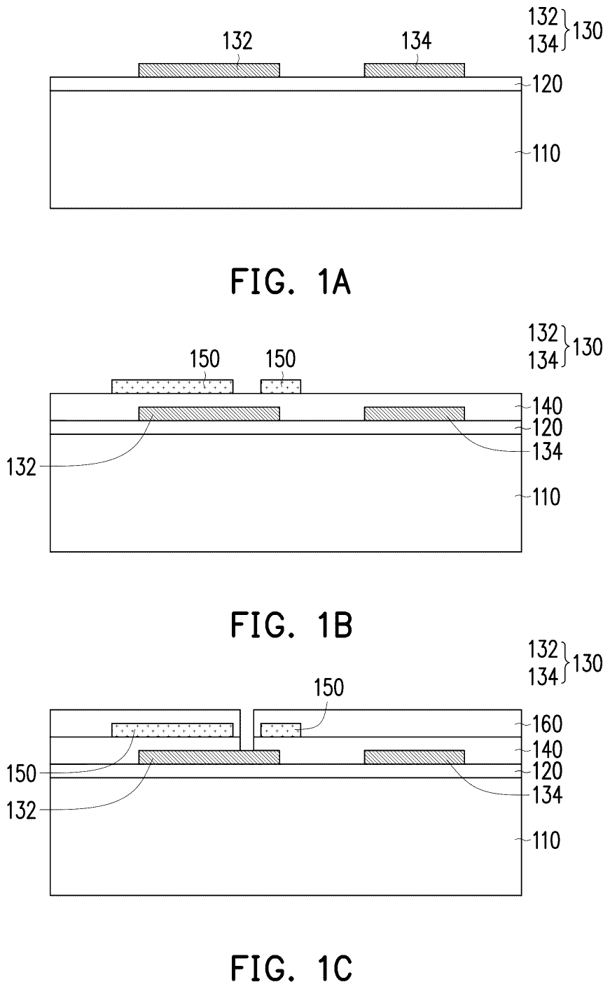

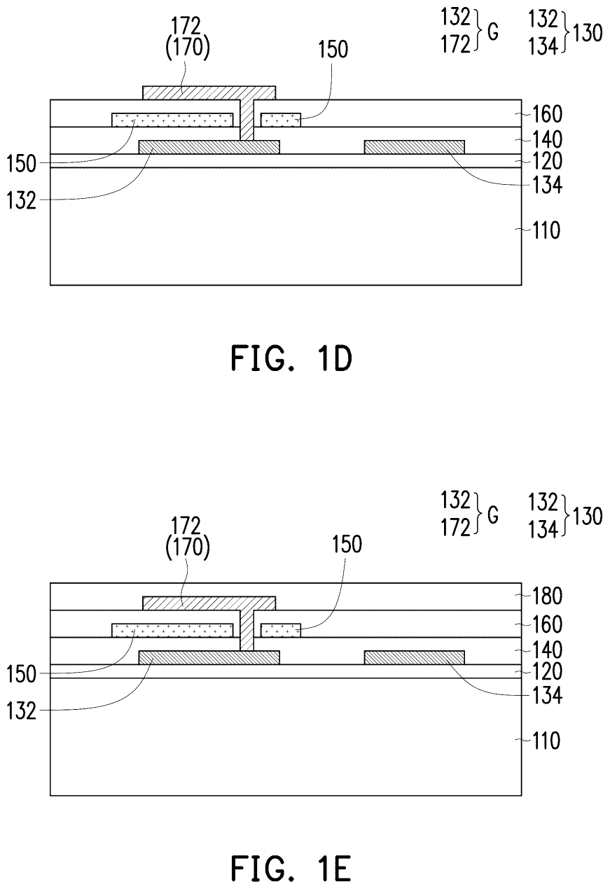

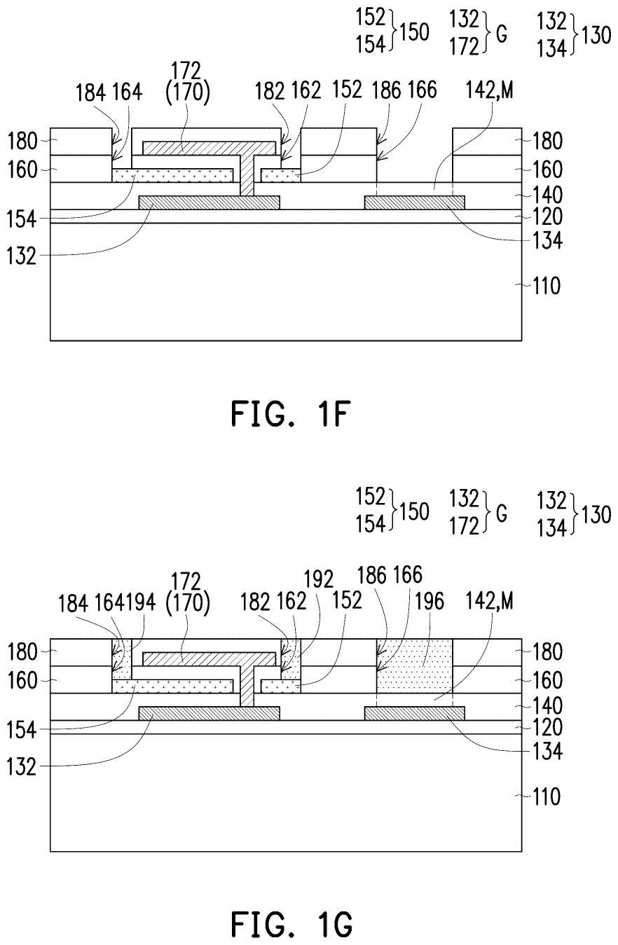

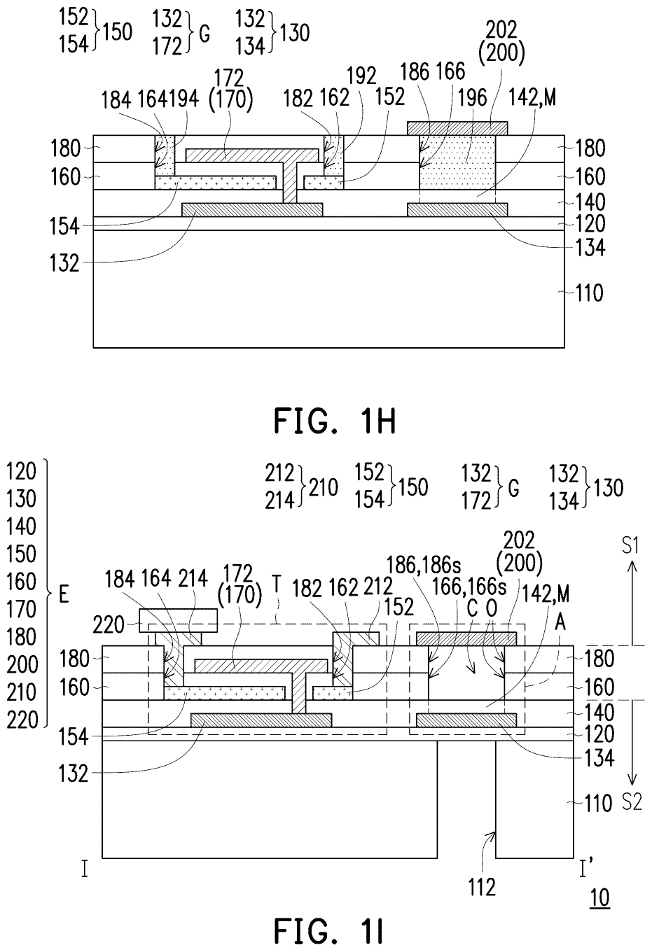

FIGS. 1A to 1I are schematic cross-sectional views of the manufacturing process of an electronic device according to one embodiment of this disclosure.

Referring to FIG. 1A, first, a base 110 is provided. The base 110 is flexible and stretchable. For example, in this embodiment, the material of base 110 may include polyimide (PI), polyethylene naphthalate (PEN), polyethylene terephthalate (PET), polycarbonates (PC), polyether sulfone (PES) or polyarylate, other suitable materials or a combination of at least two of the aforementioned materials, but this disclosure is not limited to thereto.

Next, a buffer layer 120 is formed on the base 110. In this embodiment, the buffer layer 120 may completely cover the base 110. In this embodiment, a material of the buffer layer 120 may be an inorganic material (such as silicon oxide, silicon nitride, silicon oxynitride, or a stacked layer of at least two of the above materials), an organic material, or a combination of the above.

Next, a first conductive layer 130 is formed on the buffer layer 120, wherein the first conductive layer 130 includes the first electrode 134. In this embodiment, the first conductive layer 130 may optionally include a first control terminal 132, wherein the first control terminal 132 and the first electrode 134 are structurally separated from each other. Based on conductivity considerations, the first conductive layer 130 is generally made of metal material. However, this disclosure is not limited thereto. According to other embodiments, the first conductive layer 130 may use other conductive materials, such as alloys, nitrides of metal materials, oxides of metal materials, oxynitrides of metal materials, or stacked layers of a metal material and other conductive material.

Referring to FIG. 1B, another buffer layer 140 is formed on the buffer layer 120 to cover the first conductive layer 130. In this embodiment, a material of the buffer layer 140 may be an inorganic material (such as silicon oxide, silicon nitride, silicon oxynitride, or a stacked layer of at least two of the above materials), an organic material, or a combination of the above.

Referring to FIG. 1B, next, a semiconductor pattern 150 is formed on the buffer layer 140. In this embodiment, the semiconductor pattern 150 at least partially overlaps the first control terminal 132. The semiconductor pattern 150 may be a single layer or multi-layer structure. In this embodiment, a material of the semiconductor pattern 150 may be polycrystalline silicon, amorphous silicon, microcrystalline silicon, single crystal silicon, organic semiconductor materials, oxide semiconductor materials (such as indium zinc oxide, indium gallium zinc oxide, or other suitable materials, or combinations of the above), or other suitable materials, or containing dopant in the above materials, or combinations of the above.

Referring to FIG. 1C, next, an insulation layer 160 is formed on the buffer layer 140 to cover the semiconductor pattern 150. In this embodiment, a material of the insulation layer 160 may be an inorganic material (such as silicon oxide, silicon nitride, silicon oxynitride, or a stacked layer of at least two of the above materials), an organic material, or a combination of the above.

Referring to FIG. 1D, next, a second conductive layer 170 is formed on the insulation layer 160, where the second conductive layer 170 includes a second control terminal 172. In this embodiment, the second control terminal 172 of the second conductive layer 170 and the first control terminal 132 of the first conductive layer 130 may be electrically connected to each other to form a gate G, but this disclosure is not limited thereto. Based on conductivity considerations, the second conductive layer 170 is generally made of a metal materials. However, this disclosure is not limited thereto. According to other embodiments, the second conductive layer 170 may use other conductive materials, such as alloys, nitrides of metal materials, oxides of metal materials, oxynitrides of metal materials, or stacked layers of a metal material and other conductive material.

Referring to FIG. 1E, next, an intermediate dielectric layer 180 is formed on the insulation layer 160 to cover the second conductive layer 170. In this embodiment, a material of the intermediate dielectric layer 180 may be an inorganic material (such as silicon oxide, silicon nitride, silicon oxynitride, or a stacked layer of at least two of the above materials), an organic material, or a combination of the above.

Referring to FIG. IF, next, first openings 162, 182, second openings 164, 184 and third openings 166, 186 are formed in the intermediate dielectric layer 180 and the insulation layer 160, wherein the first opening 182 of the intermediate dielectric layer 180 and the first opening 162 of the insulation layer 160 overlap and expose an area 152 of the semiconductor pattern 150, the second opening 184 of the intermediate dielectric layer 180 and the second opening 164 of the insulation layer 160 overlap and expose another area 154 of the semiconductor pattern 150, the third opening 186 of the intermediate dielectric layer 180 and the third opening 166 of the insulation layer 160 overlap and expose a portion 142 of the buffer layer 140 on the first electrode 134. In this embodiment, the portion 142 of the buffer layer 140 may be used as an oscillating membrane M.

Referring to FIG. 1G, in this embodiment, a first sacrifice pattern 192, a second sacrifice pattern 194 and a third sacrifice 196 are formed in the first openings 162, 182, the second openings 164, 184 and the third openings 166, 186 of the intermediate dielectric layer 180 and the insulation layer 160. In this embodiment, the first sacrifice pattern 192, the second sacrifice pattern 194 and the third sacrifice pattern 196 substantially fill up the first openings 162, 182, the second openings 164, 184 and the third openings 166, 186, but this disclosure is not limited to thereto.

Referring to FIG. 1H, in this embodiment, next, a third conductive layer 200 is formed

on the third sacrifice pattern 196 and the intermediate dielectric layer 180. The third conductive layer 200 includes a second electrode 202. The second electrode 202 overlaps the first electrode 134.

Referring to FIG. 1H and FIG. 1I, next, the first sacrifice pattern 192, the second sacrifice pattern 194 and the third sacrifice pattern 196 in the first openings 162, 182, the second openings 164, 184 and the third openings 166, 186 are removed, to free up the first openings 162, 182, the second openings 164, 184 and the third openings 166, 186 of the intermediate dielectric layer 180 and the insulation layer 160. At least one portion of a side walls 186s defining the third opening 186 of the intermediate dielectric layer 180, at least one portion of a side walls 166s defining the third opening 166 of the insulation layer 160, a portion 142 of the buffer layer 140 and the second electrode 202 surround the cavity C of the transducing structure A.

Referring to FIG. 1I, next, a fourth conductive layer 210 is formed on the intermediate dielectric layer 180. The fourth conductive layer 210 includes a first terminal 212 and a second terminal 214. The first terminal 212 is disposed on the intermediate dielectric layer 180 and is electrically connected to an area 152 of the semiconductor pattern 150 through the first openings 162 and 182 of the intermediate dielectric layer 180 and the insulation layer 160. The second terminal 214 is disposed on the intermediate dielectric layer 180 and is electrically connected to another area 154 of the semiconductor pattern 150 through the second openings 164 and 184 of the intermediate dielectric layer 180 and the insulation layer 160. Based on conductivity considerations, the fourth conductive layer 210 is generally made of a metal material. However, this disclosure is not limited thereto. According to other embodiments, the fourth conductive layer 210 may use other conductive materials, such as alloys, nitrides of metal materials, oxides of metal materials, oxynitrides of metal materials, or stacked layers of a metal material and other conductive material.

Referring to FIG. 1I, next, the light emitting element 220 is electrically connected to the second terminal 214. At this point, the electronic device 10 of this embodiment is completed. In this embodiment, the light emitting element 220 is, for example, a micro light emitting diode (μLED), but this disclosure is not limited to thereto. In addition, in this embodiment, an opening 112 overlapping the cavity C may be selectively formed in the base 110. However, this disclosure is not limited to thereto. According to other embodiments, the opening 112 may not be formed.

Referring to FIG. 1I, in this embodiment, an element layer E may include the buffer layer 120, the first conductive layer 130, the buffer layer 140, the semiconductor pattern 150, the insulation layer 160, the second conductive layer 170, the intermediate dielectric layer 180, the fourth conductive layer 210 and the light emitting element 220. In this embodiment, an opening O of the element layer E may be formed by the side walls 186s of the intermediate dielectric layer 180 and the side walls 166s of the insulation layer 160, but this disclosure is not limited to thereto.

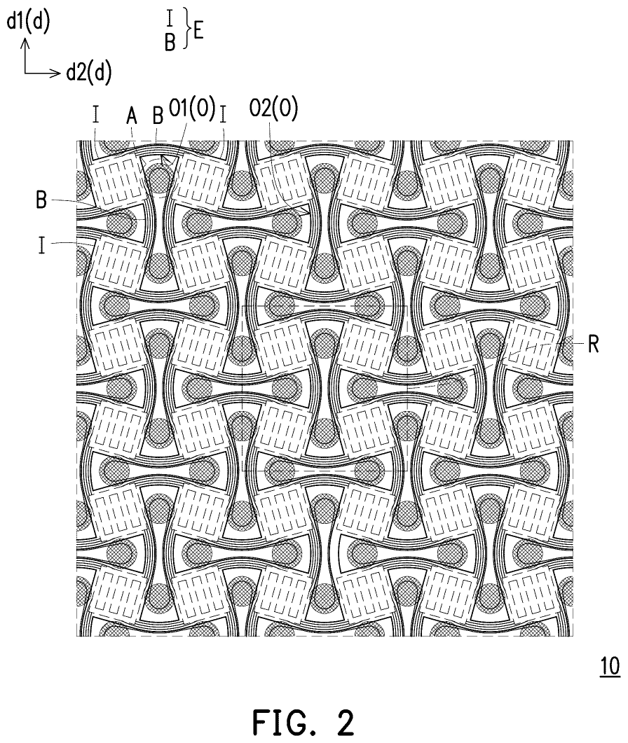

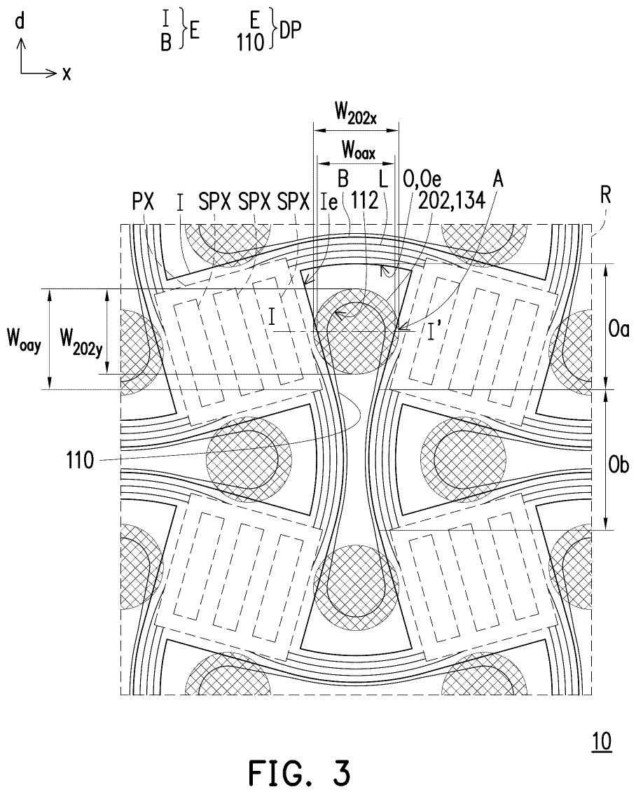

FIG. 2 is a schematic top view of an electronic device according to an embodiment of the present disclosure. FIG. 3 is a partially enlarged schematic diagram of an electronic device according to an embodiment of this disclosure. FIG. 3 shows part R of the electronic device 10 of FIG. 2. FIG. 1I corresponds to a section line I-I′ of FIG. 3.

Referring to FIG. 1I, FIG. 2 and FIG. 3, the electronic device 10 includes the element layer E. The element layer E includes island portions I, bridge portions B and openings O. The island portions I have pixel structures PX. Each of the pixel structures PX includes at least one sub-pixel structure SPX. Each of the at least one sub-pixel structure SPX includes at least one thin film transistor T and at least one light emitting element 220 electrically connected to the thin film transistor T. For example, in this embodiment, each of the island portions I has a pixel structure PX, and the pixel structure PX may include three sub-pixel structures SPX used to display red, blue and green respectively, but this disclosure is not limited to thereto.

The bridge portions B connect the island portions I. Each of the bridge portions B has at least one wire L. Wires L of the bridge portions B are electrically connected to the pixel structures

PX. For example, in this embodiment, the wires L of the bridge portions B may include a gate driving lines, a common line, a power line, a data line, etc., but this disclosure is not limited to thereto. In this embodiment, each of the wires L may be formed in the first conductive layer 130, the second conductive layer 170, the third conductive layer 200, the fourth conductive layer 210, other conductive layer, or a combination of the above.

The island portions I and the bridge portions B of the element layer E define openings O. For example, in this embodiment, four island portions I are arranged in a 2×2 matrix, the four island portions I are connected to each other through four bridge portions B, each of the four bridge portions B connects two adjacent island portions I of the four island portions I, and an opening O may be surrounded by the four island portions I and the four bridge portions B. In this embodiment, edges Ie and Oe of the opening O defined by the four island portions I and the four bridge portions B may include the side wall 186s of the intermediate dielectric layer 180 and the side wall 166s of the insulation layer 160, but this disclosure does not use thereto. In this embodiment, each of the openings O extends in an opening extension direction d, and the openings O may optionally include first openings O1 and second openings 02, wherein an opening extension direction dl of each of the first openings O1 intersects with an opening extension direction d2 of each of the second openings O2, but this disclosure is not limited to thereto.

Each of the openings O has a top side S1 and a bottom side S2 opposites to each other. At least one light emitting element 220 is located on the top side S1. The electronic device 10 includes transducing structures A. Each of the transducing structure A overlaps with a corresponding opening O. Each of the transducing structure A includes a first electrode 134 disposed on the bottom side S2 of the opening O and a second electrode 202 disposed on the top side S1 of the opening O, wherein a portion of the opening O of the element layer E is a cavity C of the transducing structure A.

Each of the transducing structure A further includes an oscillating membrane M disposed on the bottom side S2 of the opening O and connected to the first electrode 134. For example, in this embodiment, the electronic device 10 further includes a base 110, and the thin film transistor T includes a semiconductor pattern 150, a first terminal 212, a second terminal 214, and a buffer layer 140, the first terminal 212 and the second terminal 214 are electrically connected to two different areas 152 and 154 of the semiconductor pattern 150, respectively, the buffer layer 140 is located between the first terminal 212 and the base 110, and a portion 142 of the buffer layer 140 extending to the first electrode 134 of the transducing structure A may be used as the oscillating membrane M of the transducing structure A.

In this embodiment, the thin film transistor T further includes an intermediate dielectric layer 180, the intermediate dielectric layer 180 is disposed between the first terminal 212 and the semiconductor pattern 150, the intermediate dielectric layer 180 has an opening (i.e. the third opening 186) overlapping the first electrode 134, the opening (i.e. the third opening 186) of the intermediate dielectric layer 180 is at least one portion of the cavity C of the transducing structure A, and the second electrode 202 is suspended on the intermediate dielectric layer 180.

In this embodiment, the opening O of the element layer E has an opening end portion Oa overlapping the second electrode 202, the opening O of the element layer E extends in an opening extension direction d, a width W202x of the second electrode 202 in a direction x perpendicular to the opening extension direction d is greater than a width Woax of the opening end portion Oa in the direction x. Furthermore, in this embodiment, a width W202y of the second electrode 202 in the opening extension direction d is less than a width Woay of the opening end portion Oa in the opening extension direction d. In this embodiment, the opening O of the element layer E may have an opening extension portion Ob connected to the opening end portion Oa, and the second electrode 202 may not be provided on the top side S1 of the opening extension portion Ob.

The base 110 and the element layer E may be regarded as a stretchable display panel DP of electronic device 10. It is worth noting that a portion of the opening O of the stretchable display panel DP itself is used as the cavity C of the transducing structure A. In this way, the electronic device 10 can integrate display and transducer functions, and has the advantage of being thin.

The applications of the electronic device 10 are diverse. Taking application in tactile feedback displays as an example, the cavity C of the electronic device 10 can be used to generate ultrasonic waves. The ultrasonic waves form standing waves at specific wavelengths. By vibrating the air through standing waves, the human body can experience tactile feedback. Through the transducing structures A, electronic device 10 can achieve precise feedback. In one embodiment, switches (not shown) may be used to control the transducing structures A respectively. By controlling the switches of different transducing structures A, or changing the timing, the waveform of the standing wave can be changed, thereby making the human body feel different tactile sensations. In one embodiment, beamforming related technology can be used to change the waveform provided by the transducing structure A to achieve different feedback feelings. Taking the application in medical ultrasound systems as an example, the electronic device 10 integrating the stretchable display panel DP and the transducing structures A may be made into an attached design. After being attached to the patient's skin, an image can be seen directly through the stretchable display panel DP.

In the following embodiment, the reference numerals and part of the description of the foregoing embodiment are applied, where the same reference numerals are used to indicate the same or similar components, and descriptions of the same technical contents are omitted. Reference may be made to the foregoing embodiment for the omitted descriptions, which will not be repeated in following embodiment.

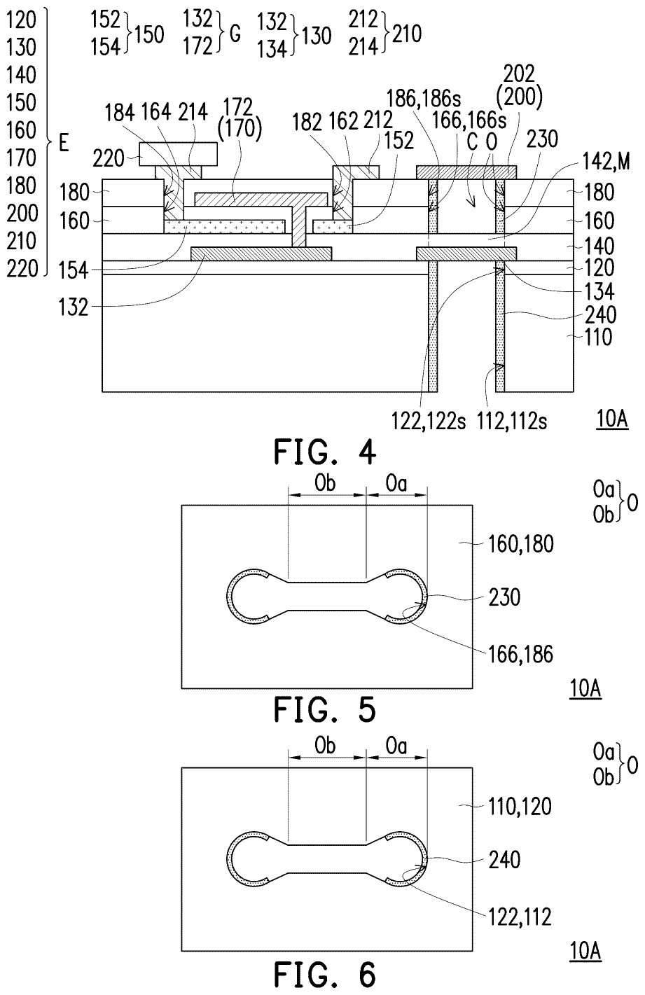

FIG. 4 is a schematic cross-sectional view of an electronic device according to another embodiment of the present disclosure. FIG. 5 is a schematic top view of the insulation layer, the intermediate dielectric layer and the deformation suppression structure of the electronic device according to another embodiment of the present disclosure. FIG. 6 is a schematic bottom view of the base, buffer layer and the deformation suppression structure of the electronic device of another embodiment of the disclosure.

Referring to FIG. 4, FIG. 5 and FIG. 6, the electronic device 10A of this embodiment is similar to the aforementioned electronic device 10. The main difference between the two is that the electronic device 10A further includes deformation suppression structures 230 and 240.

Specifically, in this embodiment, the electronic device 10A further includes a deformation suppression structure 230. The opening O of the element layer E has an opening end portion Oa overlapping the second electrode 202. The element layer E has side walls 166s and 186s that define the opening end portion Oa, and the deformation suppression structure 230 covers the side walls 166s, 186s. In this embodiment, the insulation layer 160 and the intermediate dielectric layer 180 have side walls 166s and 186s that define the opening end portion Oa, and a hardness of the deformation suppression structure 230 is greater than a hardness of the insulation layer 160 and a hardness of the intermediate dielectric layer 180. The deformation suppression structure 230 can suppress the deformation of the cavity C of the transducing structure A to avoid changes in the ultrasonic frequency. In this embodiment, in the top view, the deformation suppression structure 230 may be roughly C-shaped, but this disclosure is not limited to thereto.

In this embodiment, the electronic device 10A may further include another deformation suppression structure 240. The buffer layer 120 has an opening 122. The opening 122 of the buffer layer 120 overlaps with the opening 112 of the base 110. The buffer layer 120 has side walls 122s defining the opening 122. The base 110 has side walls 112s defining the opening 112. Another deformation suppression structure 240 may be disposed on the side wall 122s of the buffer layer 120 and the side wall 112s of the base 110. Another deformation suppression structure 240 also helps to suppress the deformation of the cavity C.

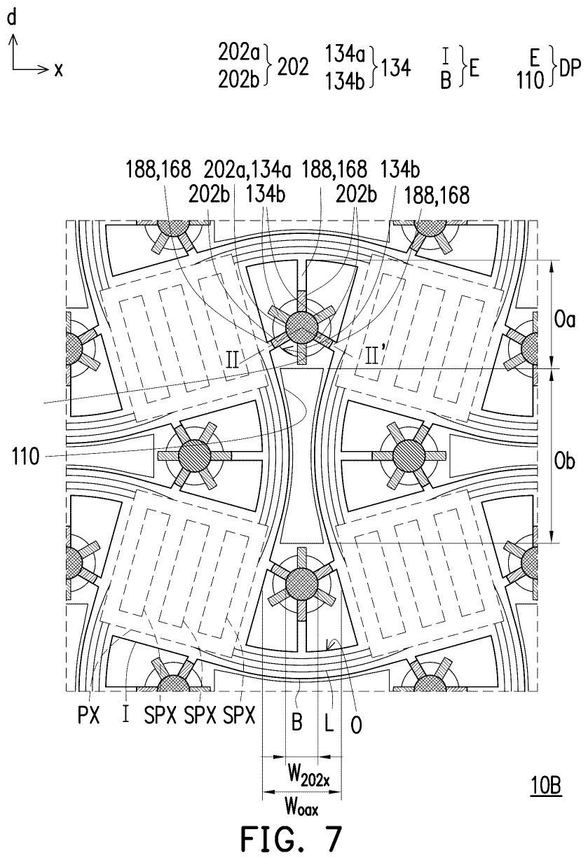

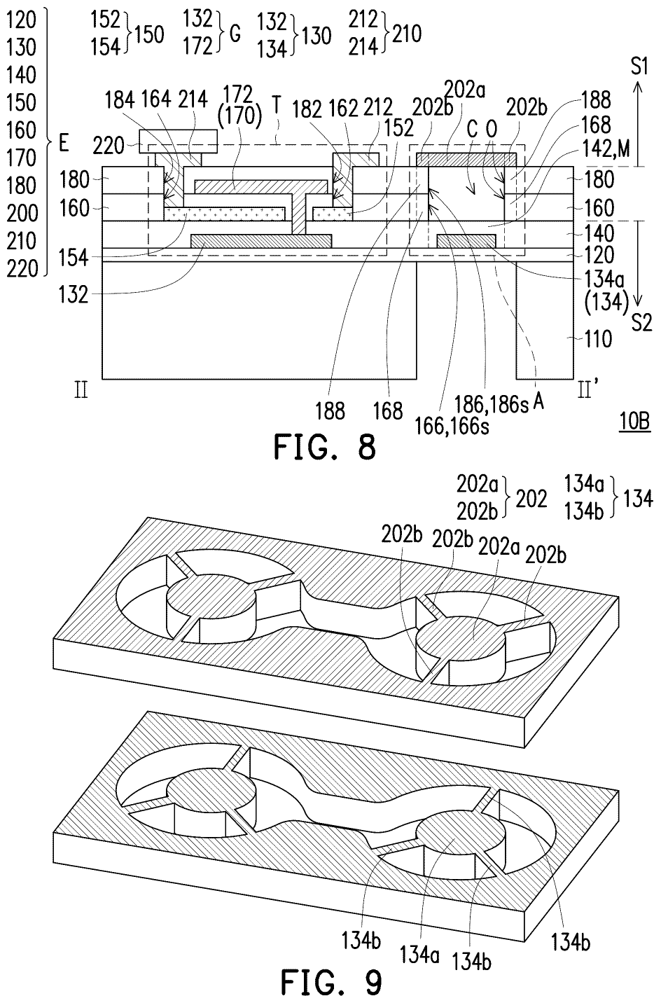

FIG. 7 is a top view and enlarged schematic diagram of an electronic device according to another embodiment of the disclosure. FIG. 8 is a schematic cross-sectional view of an electronic device according to another embodiment of the present disclosure. FIG. 8 corresponds to a section line II-II' of FIG. 7. FIG. 9 is a schematic three-dimensional view of the first electrode and the second electrode of the transducing structure of the electronic device according to another embodiment of the present disclosure.

Referring to FIGS. 7, 8 and 9, the electronic device 10B of this embodiment is similar to the aforementioned electronic device 10. The main difference between the two is that the first electrode 134 and the second electrode 202 of the transducing structure A of the electronic device 10B of this embodiment are different from the first electrode 134 and the second electrode 202 of the transducing structure A of the electronic device 10 of the previous embodiment.

Referring to FIGS. 7, 8 and 9, in this embodiment, the first electrode 134 of the transducing structure A includes a first main body portion 134a and at least one first lead portion 134b extending outward from the first main body portion 134a. The second electrode 202 of the transducing structure A includes the second main body portion 202a and at least one second lead portion 202b extending outward from the second main body portion 202a. The first main body portion 134a overlaps the second main body portion 202a, and the at least one first lead portion 134b is staggered with the at least one second lead portion 202b. Since the first lead portion 134b and the second lead portion 202b are staggered, when the transducing structure A is working, the first electrode 134 and/or the second electrode 202 are not easily to resonate accordingly.

In this embodiment, the opening O of the element layer E has an opening end portion Oa overlapping the second electrode 202. The opening O of the element layer E extends in an opening extension direction d. A width W202ax of the second main body portion 202a of the second electrode 202 in a direction x perpendicular to the opening extension direction d is less than or equal to the width Woax of the opening end portion Oa in the direction x.

In this embodiment, the thin film transistor T includes an intermediate dielectric layer 180. The intermediate dielectric layer 180 is disposed between the first terminal 212 and the semiconductor pattern 150. The intermediate dielectric layer 180 has at least one connecting pattern 188 located in the opening end portion Oa. The second electrode 202 of the transducing structure A includes a second main body portion 202a and at least one second lead portion 202b extending outward from the second main body portion 202a. The at least one second lead portion 202b of the second electrode 202 of the transducing structure A is disposed on at least one connecting pattern 188 of the intermediate dielectric layer 180. In this embodiment, the second main body portion 202a of the second electrode 202 of the transducing structure A may be suspended on at least one connecting pattern 188 of the intermediate dielectric layer 180.

In this embodiment, the insulation layer 160 may have at least one connecting pattern 168 located in the opening end portion Oa, and at least one second lead portion 202b of the second electrode 202 of the transducing structure A is further disposed on the at least one connecting pattern 168 of the insulation layer 160. In this embodiment, the second main body portion 202a of the second electrode 202 of the transducing structure A may be further suspended on the at least one connecting pattern 168 of the insulation layer 160.

Compared with the aforementioned electronic device 10, the characteristics of the transducing structure A of the electronic device 10B of this embodiment are less susceptible to the stretching of the stretchable display panel DP.

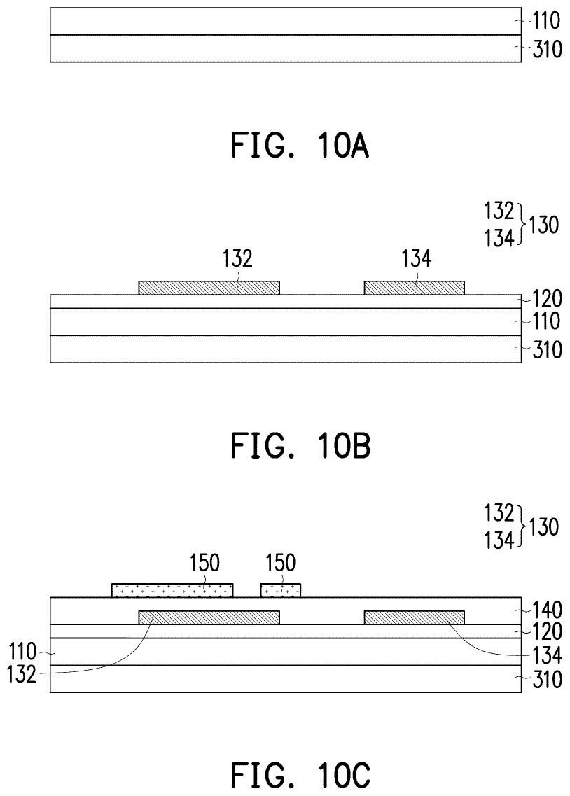

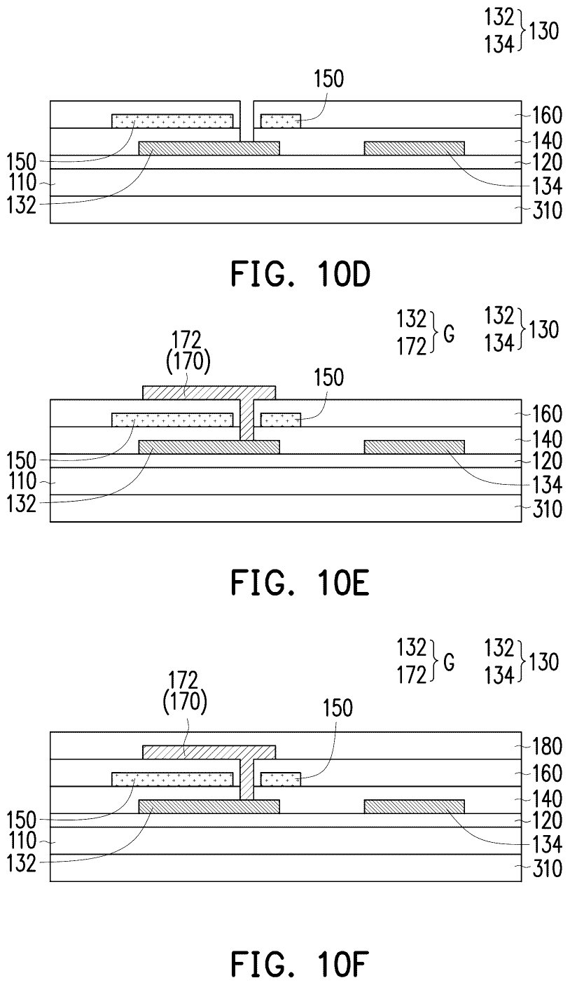

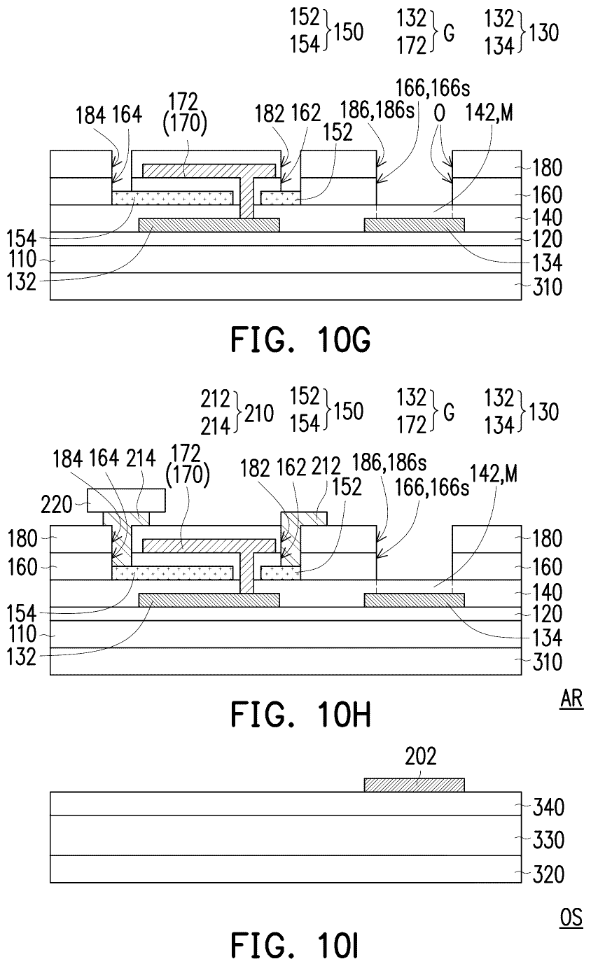

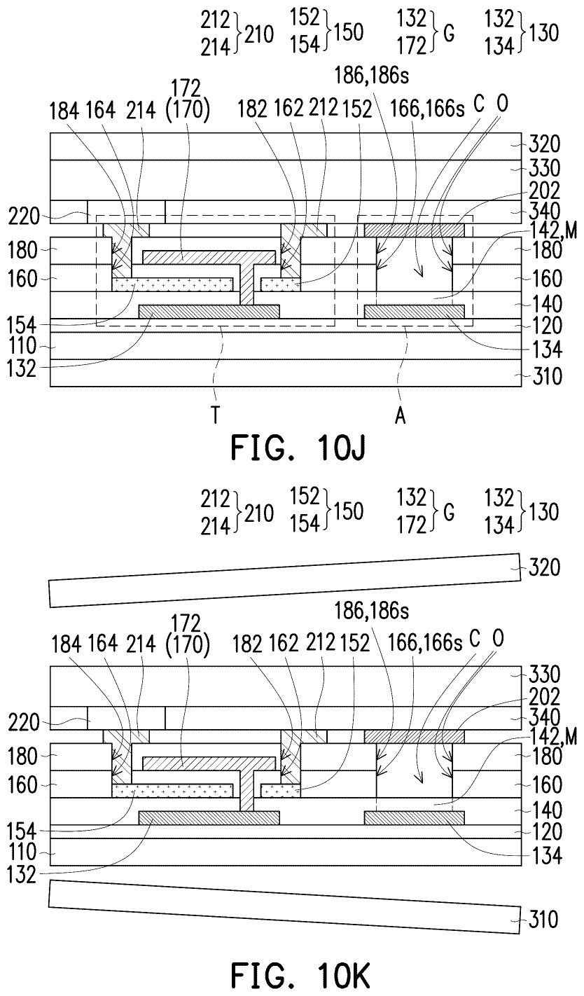

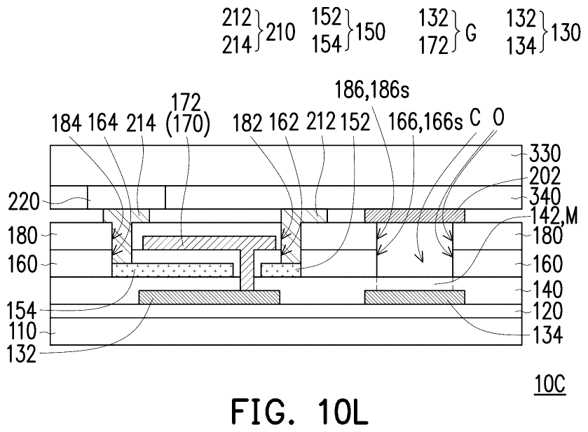

FIGS. 10A to 10L are schematic cross-sectional views of the manufacturing process of an electronic device according to yet another embodiment of the present disclosure.

The manufacturing process of the electronic device 10C of FIGS. 10A to 10L is similar to the manufacturing process of the electronic device 10 of FIGS. 1A to 1I. The main difference between the two is that in the embodiment of FIGS. 10A to 10L, the first electrode 134 and the second electrode 202 are respectively formed on different hard substrates 310 and 320, and then assembled into the transducing structure A. Detailed description is as follows with reference to FIGS. 10A to 10L.

Referring to FIG. 10A, first, a hard substrate 310 is provided. Then, a base 110 is formed on the hard substrate 310, where the base 110 has elasticity and stretchability. Referring to FIG. 10B, next, a buffer layer 120 is formed on the base 110, and a first conductive layer 130 is formed on the buffer layer 120, wherein the first conductive layer 130 includes a first control terminal 132 and a first electrode 134 that are structurally separated from each other. Referring to FIG. 10C, next, another buffer layer 140 is formed on the buffer layer 120 to cover the first control terminal 132 and the first electrode 134. Referring to FIG. 10C, next, a semiconductor pattern 150 is formed on the buffer layer 140, wherein the semiconductor pattern 150 at least partially overlaps the first control terminal 132.

Referring to FIG. 10D, next, an insulation layer 160 is formed on the buffer layer 140 to cover the semiconductor pattern 150. Referring to FIG. 10E, next, a second conductive layer 170 is formed on the insulation layer 160, wherein the second conductive layer 170 includes a second control terminal 172, and the second control terminal 172 of the second conductive layer 170 and the first control terminal 132 of the first conductive layer 130 are electrically connected to each other to form a gate G.

Referring to FIG. 10F, next, an intermediate dielectric layer 180 is formed on the insulation layer 160 to cover the second control terminal 172. Referring to FIG. 10G, next, first openings 162, 182, second openings 164, 184 and third openings 166, 186 are formed in the intermediate dielectric layer 180 and the insulation layer 160, wherein the first opening 182 of the intermediate dielectric layer 180 and the first opening 162 of the insulation layer 160 overlap and expose an area 152 of the semiconductor pattern 150, and the second opening 184 of the intermediate dielectric layer 180 and the second opening 164 of the insulation layer 160 overlap and expose another area 154 of the semiconductor pattern 150. The third opening 186 of the intermediate dielectric layer 180 and the third opening 166 of the insulation layer 160 overlap and expose a portion 142 of the buffer layer 140 on the first electrode 134. The portion 142 of the buffer layer 140 is used as an oscillating membrane M connected to the first electrode 134.

Referring to FIG. 10H, next, a fourth conductive layer 210 is formed on the intermediate dielectric layer 180. The fourth conductive layer 210 includes a first terminal 212 and a second terminal 214. The first terminal 212 is disposed on the intermediate dielectric layer 180 and is electrically connected to the area 152 of the semiconductor pattern 150 through the first openings 162 and 182 of the intermediate dielectric layer 180 and the insulation layer 160. The second terminal 214 is disposed on the intermediate dielectric layer 180 and is electrically connected to another area 154 of the semiconductor pattern 150 through the second openings 164 and 184 of the intermediate dielectric layer 180 and of the insulation layer 160. Next, the light emitting element 220 is electrically connected to the second terminal 214. At this point, the active element substrate AR is completed. The active element substrate AR includes the hard substrate 310, a base 110 having elasticity and stretchability, the buffer layer 120, the first conductive layer 130 having the first electrode 134, the buffer layer 140, the semiconductor pattern 150, the insulation layer 160, the third conductive layer 200, the intermediate dielectric layer 180, the fourth conductive layer 210 and the light emitting element 220.

Referring to FIG. 10I, another hard substrate 320 is provided, another base 330 having elasticity and stretchability is formed on another hard substrate 320, a buffer layer 340 is formed on another base 330, and a second electrode 202 is formed on the buffer layer 340. At this point, an opposite substrate OS is completed. The opposite substrate OS includes the hard substrate 320, another base 330 having elasticity and stretchability, the buffer layer 340 and the second electrode 202.

Referring to FIG. 10H, FIG. 101 and FIG. 10J, next, the active element substrate AR and the opposition substrate OS are assembled, so that the second electrode 202 of the opposition substrate OS and at least one portion of the third openings 186, 166 of the intermediate dielectric layer 180 and the insulation layer 160 of the active element substrate AR surround a cavity C of the transducing structure A. Referring to FIG. 10K and FIG. 10L, next, remove the hard substrates 310 and 320 from the bases 110 and 330 respectively. At this point, the electronic device 10C of this embodiment is completed.

Referring to FIG. 10L, the electronic device 10C of this embodiment is similar to the aforementioned electronic device 10. The difference between the two is that the electronic device 10C of FIG. 10L further includes another base 330 and another buffer layer 340 wherein another base 330 is disposed opposite to the base 110, the buffer layer 340 is disposed between another base 330 and the second electrode 202 of the transducing structure A.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device comprising:
an element layer comprising:
a plurality of island portions having pixel structures, wherein each of the pixel structures includes a thin film transistor and at least one light emitting element electrically connected to the thin film transistor;
a plurality of bridge portions connected to the island portions, wherein each of the bridge portions has at least one wire, and wires of the bridge portions are electrically connected to the pixel structures; and
a plurality of openings, wherein the island portions and the bridge portions define the openings, each of the openings has a top side and a bottom side opposite to each other, and the at least one light emitting element is located on the top side; and
a plurality of transducing structures, wherein each of the transducing structures overlaps a opening of the openings, and the each of the transducing structures comprises:
a first electrode, disposed on the bottom side of the opening; and
a second electrode, disposed on the top side of the opening, wherein a portion of the opening is a cavity of the each of the transducing structures.

2. The electronic device according to claim 1, further comprising:
a base, wherein the thin film transistor comprises a semiconductor pattern, a first terminal, a second terminal and a buffer layer, the first terminal and the second terminal are electrically connected to two different areas of the semiconductor pattern respectively, the buffer layer is located between the first terminal and the base, and a portion of the buffer layer extending to the first electrode of the each of the transducing structures is an oscillating membrane of the each of the transducing structures.

3. The electronic device according to claim 2, wherein the thin film transistor further comprises an intermediate dielectric layer, the intermediate dielectric layer is disposed between the first terminal and the semiconductor pattern, the intermediate dielectric layer has an opening overlapping the first electrode, the opening of the intermediate dielectric layer is at least one portion of the cavity of the each of the transducing structures, and the second electrode of the each of the transducing structures is suspended on the intermediate dielectric layer.

4. The electronic device according to claim 1, wherein the opening of the element layer has an opening end portion overlapping the second electrode, the opening of the element layer extends in an opening extension direction, and a width of the second electrode in a direction perpendicular to the opening extension direction is greater than a width of the opening end portion in the direction.

5. The electronic device according to claim 1, wherein the opening of the element layer has an opening end portion overlapping the second electrode, the opening of the element layer extends in an opening extension direction, a width of the second electrode in the opening extension direction is less than a width of the opening end portion in the opening extension direction.

6. The electronic device according to claim 1, wherein the first electrode of the each of the transducing structures comprises a first main body portion and at least one first lead portion extending outward from the first main body portion, the second electrode of the each of the transducing structures comprises a second main body portion and at least one second lead portion extending outward from the second main body portion, the first main body portion overlaps the second main body portion, and the at least one first lead portion is staggered with the at least one second lead portion.

7. The electronic device according to claim 1, wherein the second electrode of the each of the transducing structures comprises a second main body portion and second lead portions extending outward from the second main body portion, the opening of the element layer has an opening end portion overlapping the second electrode, the opening of the element layer extends in an opening extension direction, and a width of the second main body portion of the second electrode in a direction perpendicular to the opening extension direction is less than or equal to a width of the opening end portion in the direction.

8. The electronic device according to claim 1, wherein the opening of the element layer has an opening end portion overlapping the second electrode, the thin film transistor comprises a semiconductor pattern, a first terminal, a second terminal and an intermediate dielectric layer, the first terminal and the second terminal are electrically connected to two different areas of the semiconductor pattern respectively, the intermediate dielectric layer is disposed between the first terminal and the semiconductor pattern, the intermediate dielectric layer has at least one connecting pattern located within the opening end portion, the second electrode of the each of the transducing structures comprises a second main body portion and at least one second lead portion extending outward from the second main body portion, and the at least one second lead portion is disposed on the at least one connecting pattern of the intermediate dielectric layer.

9. The electronic device according to claim 8, wherein the second main body portion of the second electrode of the each of the transducing structures is suspended on the at least one connecting pattern of the intermediate dielectric layer.

10. The electronic device according to claim 1, further comprising:
a deformation suppression structure, wherein the opening of the element layer has an opening end portion overlapping the second electrode, the element layer has a side wall defining the opening end portion, and the deformation suppression structure covers the side wall.
